(19) United States
(12) Patent Application Publication
(10) Pub. No.: US 2026/0251734 A1
(43) Pub. Date: Aug. 27, 2026

(54) DEVICE AND METHOD FOR DETECTING MAGNETIC FIELDS

(71) Applicant: Infineon Technologies AG, Neubiberg (DE)

(72) Inventor: Udo AUSSERLECHNER, Villach (AT)

(21) Appl. No.: 19/543,917

(22) Filed: Feb. 19, 2026

(30) Foreign Application Priority Data
Feb. 25, 2025 (DE) 102025107166.7

(51) Int. Cl. G01R 33/07; G01R 33/02

(52) U.S. Cl. CPC G01R 33/07; G01R 33/0206

(57) ABSTRACT

A device for detecting magnetic fields includes a non-planar Hall effect region. The device includes at least four contacts arranged along a border of the non-planar Hall effect region. The device includes a circuit arrangement configured so as, in each of different operating phases, to channel in current through at least two different pairs of contacts and to measure voltages between at least two other pairs of contacts. The device includes a processing unit configured to identify various magnetic field components by way of different combinations of the measured voltages from the different operating phases.

### CROSS REFERENCE TO RELATED APPLICATION

This application claims priority to Germany Patent Application No. 102025107166.7 filed on Feb. 25, 2025, the content of which is incorporated by reference herein in its entirety.

### TECHNICAL FIELD

The present disclosure relates to the technical field of magnetic field sensors, in particular to the detection of multidimensional magnetic field components using Hall sensors.

### BACKGROUND

Hall sensors are widely used to determine magnetic fields in various applications, including position and motion sensors, current measurement, and magnetic navigation. Conventional Hall sensors typically consist of a flat Hall plate that is sensitive to a single magnetic field component, while the detection of all three spatial components of a magnetic field (Bₓ, B_{y}, B_{z}) usually requires the use of multiple differently aligned Hall elements. In known solutions, a combination of a horizontal Hall plate and multiple vertical Hall elements is often used for this purpose to allow three-dimensional measurement. A disadvantage of these approaches is that the measurement properties of the various Hall elements are not exactly consistent due to geometric and material-related differences, which can lead to calibration problems and measurement inaccuracies throughout temperature and ageing processes. In addition, a variance in the measurement signals between the various Hall sensors (e.g., different measuring properties of the sensors) is a challenge, as this can result in systematic errors during field measurement. Another difficulty is that classic planar Hall sensors or arrangements comprising multiple separate Hall plates do not always allow optimum signal processing, in particular with regard to the suppression of offset errors or discrimination between individual magnetic field components. A sensor maps a physical quantity (e.g., a magnetic field component) to an electrical quantity (e.g., a voltage). This sensor characteristic, that is to say the relationship between the voltage and the magnetic field component, is approximately linear for Hall sensors, that is to say it can be described by a straight line. Ideally, this straight line should run through the origin of the coordinate system. In reality, however, it is shifted along the axis of the magnetic field component by a certain value, the so-called offset error (also called the zero-point error).

Therefore, it is an object to provide an improved device and method for detecting magnetic fields that allow more precise and stable determination of multidimensional magnetic field components while avoiding the disadvantages of conventional sensor arrangements.

### SUMMARY

According to a first aspect of the present disclosure, a device for detecting magnetic fields is proposed. The device includes a non-planar Hall effect region. The device further includes at least four contacts arranged along a border of the non-planar Hall effect region. The device further includes a circuit arrangement configured so as, in each of different operating phases, to carry current through at least two different pairs of contacts and to measure voltages between at least two other pairs of contacts. The device further includes a processing unit configured to identify various magnetic field components by way of different combinations of the measured voltages from the different operating phases.

The device thus includes a specially shaped Hall effect region, which can be in the form of a shell-shaped structure, e.g., it has a three-dimensional geometry with two opposing, substantially larger surfaces and a comparatively smaller peripheral area that connects these surfaces to form a closed envelope. The thickness of the shell is measured perpendicular to one of its surfaces and remains small at each point of the structure relative to the lateral dimensions of the surface. At least four contacts are mounted along the borders or edges of this non-planar Hall effect region. These contacts are used to channel an electric current through different contact pairs in different operating phases while at the same time voltages between other contact pairs are measured. A circuit arrangement controls these processes, and a processing unit evaluates the measured voltages. A deliberate combination of voltage values from the different operating phases can be used to determine the individual magnetic field components (Bₓ, B_{y}, B_{z}) of an external magnetic field.

One advantage of this arrangement lies in the ability to use the non-planar Hall effect region to detect the three orthogonal magnetic field components in a single sensor with high accuracy. Placing the contacts along the borders and combining the measured voltages allows systematic errors such as offsets to be reduced and the quality of the measurement to be improved. In particular, the orientation of different areas of the Hall effect region allows a direction of the magnetic field vector in space to be accurately detected. This can lead to more precise results without requiring multiple separate Hall elements.

According to some example implementations, the non-planar Hall effect region has a polyhedral surface structure. This means that the surface of the Hall effect region can be composed of multiple planar surfaces that are connected by edges and form a three-dimensional (3D) geometric shape. This structure differs from a simple, smooth surface or a purely planar arrangement, as it has a specific spatial shape due to its faceted design. Different parts of the surface have different orientation in space. A polyhedral design of this kind allows the currents within the Hall effect region to be carried on defined, inclined surfaces, allowing better spatial separation and targeted detection of the magnetic field components to be achieved.

According to some example implementations, the non-planar Hall effect region has a pyramidal structure with inclined surfaces. The surface of this pyramid structure consists of multiple inclined surfaces that converge upwards from a base. This shape differs from a flat or planar structure and allows the spatial geometry of the region to be used in a deliberate manner to distribute electric currents and voltages in a three-dimensional space. This design allows the currents to be carried on the inclined surfaces, which can lead to more effective interaction with the magnetic fields. This helps to enable precise and unambiguous detection of the individual magnetic field components, since the geometry of the structure can be produced with high accuracy and reproducibility and can also be optimally tailored to the three-dimensional nature of the magnetic fields. It is particularly advantageous if the layer resistance in all parts of the non-planar Hall effect region is homogeneous (that is to say e.g., constant thickness of the shell-shaped geometry and constant doping profile) so that the current is distributed in a balanced manner according to the geometric symmetry of the Hall effect region in the absence of a magnetic field, and it is only under the influence of a magnetic field that small imbalances in the current flow pattern arise, which can be used to measure the magnetic field.

According to some example implementations, the pyramidal Hall effect region is in the form of an inverted and/or cropped pyramid. The Hall effect region may thus be configured to have the shape of a pyramid that is upside down and/or cropped at its tip. An inverted pyramid involves the base pointing upwards while the tip is directed downwards. A cropped pyramid involves the tip being replaced by an additional surface or a hole. In the first case, a simply connected domain is obtained; in the second case, a doubly connected domain is obtained, in which the structure has an annular opening. Both variants are modifications of the classic pyramid shape that adapt the geometry of the Hall effect region. This special design can ensure that currents within the region can be carried on clearly defined inclined surfaces without leaving the structure. This can be used to optimize interaction with magnetic fields and to ensure reliable detection of the magnetic field components. The adapted shape can also facilitate the arrangement of contacts and targeted control of the current paths.

According to some example implementations, the non-planar Hall effect region is in doubly connected form and has an annular, non-planar surface. The topology of the Hall effect region can thus have a “hole”, as a result of which the geometry of the region resembles a continuous, closed surface with an opening. This structure is not flat, but has a three-dimensional design, meaning that the entire surface can consist of inclined sections and the surface can have a spatial depth. An annular geometry of this kind allows the electric currents to be evenly distributed on the surface without leaving the region. The spatial arrangement can help to direct the currents in a deliberate manner and to optimize interaction with the magnetic fields in a way that is advantageous for detecting the magnetic field components.

According to some example implementations, the contacts or a portion thereof are arranged in respective centers of edges of a base of the non-planar Hall effect region. The contacts may thus be positioned so that they are in the respective middles of the edges that form the base of the non-planar Hall effect region. This means that at least some of the contacts may be evenly distributed along the edges and are not at the corners or at other locations on the structure. The positioning in the centers ensures that the contacts are arranged symmetrically along the base. This arrangement allows the electric currents within the Hall effect region to be evenly distributed, which can simplify measurement of the magnetic field components. The symmetry can help to reduce systematic errors in the measurement signals and to increase precision when detecting magnetic field components.

According to some example implementations, the contacts or a portion thereof are arranged in corner areas of a base of the non-planar Hall effect region. In some example implementations, the contacts are thus positioned so that they are in the corner areas of the base of the non-planar Hall effect region. This means that at least some contacts may be arranged at the points of intersection of the edges of the base and therefore have a symmetrical placement at the outermost points of the geometry. This arrangement can promote effective distribution of the electric currents within the Hall effect region and allow clear separation of the current paths. This can increase measurement accuracy, as the positioning of the contacts can facilitate precise detection of the magnetic field components.

According to some example implementations, the circuit arrangement is configured so as, in each of the operating phases, to simultaneously channel in at least two currents of equal level via different contacts. In some example implementations, the circuit arrangement is thus configured so that in each operating phase it simultaneously channels at least two electric currents of equal level through different pairs of contacts. This means that the currents are supplied to the Hall effect region in parallel, the current in both paths being essentially identical, but different contact positions being used. This configuration can help to ensure a balanced current distribution within the Hall effect region and to minimize interference or systematic errors during measurement.

According to some example implementations, the processing unit is configured to perform various additions and/or subtractions of voltages measured and weighted in the different operating phases for each of various magnetic field components. In some example implementations, the processing unit is thus configured so that it uses different combinations of the voltages measured in the different operating phases to determine each of various magnetic field components. The processing unit performs additions and/or subtractions for the voltage values and can assign specific weightings to these voltages in order to identify the respective components. This approach allows precise and clear separation of the individual magnetic field components, as a deliberate combination of the voltages can help to eliminate interference or influences from other components.

According to some example implementations, precisely four contacts are arranged in respective centers of edges of a base of the non-planar Hall effect region. The circuit arrangement is configured so as, in each of at least three operating phases, to use different pairs of the contacts for channeling in currents and to provide for different voltage taps. In some example implementations, exactly four contacts are thus positioned so that they are in the respective centers of the edges of a base of the non-planar Hall effect region. The circuit arrangement is configured so that in at least three different operating phases it selects different pairs of these contacts in order to channel in electric currents. At the same time, voltage differences between other, likewise changing contact pairs are measured in each operating phase. This arrangement allows a flexible and versatile current and voltage distribution within the Hall effect region. Systematic variation of the current paths and voltage taps can be used to optimize detection of the magnetic field components, as the different operating phases can provide different measurement information that can be supplemented and combined. This can help to produce measurements with higher precision and less influence from interference factors.

According to some example implementations, the circuit arrangement is configured so as, in each of at least three operating phases, to simultaneously channel two currents between different pairs of the four contacts and to measure at least two voltage differences between the remaining contacts, a different set of contact pairs being used for channeling in current and measuring voltage in each operating phase. In at least three different operating phases, two electric currents can thus be simultaneously channeled through different pairs of the four contacts. At the same time, the circuit arrangement measures voltage differences between the remaining contacts in each operating phase. The selection of the contact pairs for channeling in current and measuring voltage is altered in each operating phase, so that different combinations are used in the different phases. This approach can lead to measured values being obtained from different perspectives, allowing for a more comprehensive analysis of the magnetic field components. Systematic variation of the current and voltage paths can help to reduce interference signals and improve the quality of the results, as the spatial geometry of the Hall effect region can be used in an optimum manner.

According to some example implementations, a first contact (C0) is arranged on a first edge of a base of the non-planar Hall effect region, a second contact (C1) is arranged on a second edge of the base of the non-planar Hall effect region, a third contact (C2) is arranged on a third edge of the base of the non-planar Hall effect region, and a fourth contact (C3) is arranged on a fourth edge of the base of the non-planar Hall effect region. The circuit arrangement may be configured so as, in a first operating phase, to channel in a first current between the third (C2) and second (C1) contacts, to channel in a second current between the fourth (C3) and first (C0) contacts, to measure a first voltage (V23) between the third (C2) and fourth (C3) contacts and to measure a second voltage (V10) between the second (C1) and first (C0) contacts. The circuit arrangement may be configured so as, in a second operating phase, to channel in a first current between the second (C1) and first (C0) contacts, to channel in a second current between the third (C2) and fourth (C3) contacts, to measure a first voltage (V12) between the second (C1) and third (C2) contacts and to measure a second voltage (V03) between the first (C0) and fourth (C3) contacts. The circuit arrangement may be configured so as, in a third operating phase, to channel a first current into the first contact (C0) and away via the second contact (C1), to channel a second current into the third contact (C2) and away via the fourth contact (C3), to measure a first voltage (V02) between the first (C0) and third (C2) contacts and to measure a second voltage (V31) between the fourth (C3) and second (C1) contacts. In some example implementations, therefore, four contacts are arranged on the edges of a base of the non-planar Hall effect region, each contact occupying a specific position along the edges: the first contact is on the first edge, the second contact is on the second edge, the third contact is on the third edge, and the fourth contact is on the fourth edge. The circuit arrangement is configured so that different combinations of these contacts are used for channeling current and measuring voltage in different operating phases. In one operating phase, two currents are simultaneously channeled through defined contact pairs while voltages between other contact pairs are measured. In another operating phase, the current paths and voltage measurements are varied so that other contact combinations are used. This is repeated in at least three operating phases, each phase using a unique combination of current and voltage paths. This flexible arrangement of the operating phases can help to gain different measurement perspectives on the magnetic field, which allows precise separation of the magnetic field components. Varying the current and voltage paths can at the same time minimize interference signals and compensate for systematic errors, allowing the overall accuracy of the measurement to be improved.

According to some example implementations, the processing unit is configured to identify the magnetic field component Bₓ in proportion to a combination of the voltage between the first and second contacts, reduced by the voltage between the third and fourth contacts, plus the voltage between the second and third contacts, reduced by the voltage between the first and fourth contacts, and minus twice the voltage between the first and third contacts (V₁₀−V₂₃+V₁₂−V₀₃−2*V₀₂). Similarly, the processing unit is configured to identify the magnetic field component B_{y} in proportion to a combination of the negative voltage between the first and second contacts, plus the voltage between the third and fourth contacts, plus the voltage between the second and third contacts, reduced by the voltage between the first and fourth contacts, and minus twice the voltage between the fourth and second contacts (−V₁₀+V₂₃+V₁₂−V₀₃−2*V₃₁). The magnetic field component B_{z} can be identified in proportion to the sum of the voltages between the first and second contacts, the third and fourth contacts, the second and third contacts, and the first and fourth contacts (V₁₀+V₂₃+V₁₂+V₀₃). In some example implementations, the processing unit is thus configured so that it computes the magnetic field components Bₓ, B_{y} and B_{z} by way of targeted mathematical combinations of the voltages measured in different operating phases. In this case, Bₓ is determined by a formula that combines the voltage differences V₁₀, V₂₃, V₁₂, V₀₃ and V₀₂ in a specific weighting. Similarly, B_{y} is computed from a similar combination, which, however, uses other arithmetic signs and weightings of the voltages, including V₃₁. Finally, B_{z} is computed in proportion to the sum of all measured voltages V₁₀, V₂₃, V₁₂ and V₀₃, which establishes a direct relationship between the voltages and the vertical magnetic field component. This approach can ensure that each magnetic field component is determined based on a specific combination of the voltage values, allowing clear separation of the field components to be achieved. Deliberate weighting and combination of the voltages allows interference effects to be minimized and precise determination of the spatial magnetic field components to be achieved.

According to some example implementations, there is provision for precisely eight contacts, which are arranged both in the corner areas and in middle areas of edges of a base of the non-planar Hall effect region. The circuit arrangement may be configured so as, in each of at least three operating phases, to use different pairs of the contacts for channeling in currents and to provide for different voltage taps. In some example implementations, the Hall effect region thus has a total of eight contacts arranged at specific positions along the base of the non-planar structure. Some contacts are in the corner areas of the base, while others are positioned in the centers of the edges. This distribution ensures that the contacts are placed symmetrically and evenly along the entire base. The circuit arrangement is configured so that different combinations of these contacts are used to channel in electric currents and measure voltage differences between the remaining contacts in at least three operating phases. This arrangement allows flexible control of the current and voltage paths within the Hall effect region. Targeted selection of the contact pairs in the different operating phases allows a wide range of measurement perspectives on the magnetic field to be ascertained, allowing more precise determination of the magnetic field components to be achieved. The additional number and symmetrical distribution of the contacts can also increase measurement accuracy by achieving a finer resolution for the current and voltage paths within the region.

According to some example implementations, the circuit arrangement is configured so as, in each of at least three operating phases, to channel at least two simultaneous currents between different subgroups of the eight contacts and to measure multiple voltage differences between other contact pairs. In some example implementations, the circuit arrangement is thus configured so that in each of at least three different operating phases it simultaneously channels at least two electric currents through different groups of the total of eight contacts. While these currents are simultaneously flowing, voltage differences between other contact pairs are measured, the selection of the contact groups in the different phases varying to produce different combinations of currents and voltage taps. This configuration allows comprehensive collection of magnetic field information, as the simultaneous channeling of multiple currents and the measurement of multiple voltages allow different perspectives on the magnetic field to be obtained at the same time. Targeted variation of the contact combinations in the different operating phases can help to increase the spatial resolution and precision of the measurements by gathering more information about the interaction between the currents and the magnetic field.

According to some example implementations, a first contact (C0) is arranged at a centre of a first edge of a base of the non-planar Hall effect region, a second contact (C1) is arranged at a vertex between the first edge and a second edge of the base of the non-planar Hall effect region, a third contact (C2) is arranged at a centre of the second edge, a fourth contact (C3) is arranged at a vertex between the second edge and a third edge of the base of the non-planar Hall effect region, a fifth contact (C4) is arranged at a centre of the third edge, a sixth contact (C5) is arranged at a vertex between the third edge and a fourth edge of the base of the non-planar Hall effect region, a seventh contact (C6) is arranged at a centre of the fourth edge, and an eighth contact (C7) is arranged at a vertex between the fourth edge and the first edge of the base of the non-planar Hall effect region. The circuit arrangement is configured so as, in a first operating phase, to channel a first current into the second contact (C1) and away via the fourth contact (C3), to channel a second current into the sixth contact (C5) and away via the eighth contact (C7), to measure a first voltage (V15) between the second (C1) and sixth (C5) contacts, to measure a second voltage (V06) between the first (C0) and seventh (C6) contacts and to measure a third voltage (V24) between the third (C2) and fifth (C4) contacts. The circuit arrangement is configured so as, in a second operating phase, to channel a first current into the first contact (C0) and away via the third contact (C2), to channel a second current into the fifth contact (C4) and away via the seventh contact (C6), to measure a first voltage (V15) between the second (C1) and sixth (C5) contacts, to measure a second voltage (V37) between the fourth (C3) and eighth (C7) contacts, to measure a third voltage (V13) between the second (C1) and fourth (C3) contacts and to measure a fourth voltage (V75) between the eighth (C7) and sixth (C5) contacts. The circuit arrangement is configured so as, in a third operating phase, to channel a first current into the sixth contact (C5) and away via the fourth contact (C3), to channel a second current into the eighth contact (C7) and away via the second contact (C1), to measure a first voltage (VBE57) between the sixth (C5) and eighth (C7) contacts, to measure a second voltage (VBE31) between the fourth (C3) and second (C1) contacts, to measure a third voltage (VBE53) between the sixth (C5) and fourth (C3) contacts and to measure a fourth voltage (VBE71) between the eighth (C7) and second (C1) contacts. In some example implementations, therefore, eight contacts are arranged at specific positions along the edges of a base of the non-planar Hall effect region. Contacts that are in the centers of the edges alternate with contacts that are positioned at the vertices between the edges. This arrangement ensures that the contacts are evenly distributed along the base, allowing different combinations of current and voltage paths to be produced. The circuit arrangement is configured so that different contact combinations are used for channeling in current and measuring voltage in different operating phases. In the first operating phase, two parallel currents are channeled between defined contact pairs while voltage differences between other, specific contact pairs are measured. In the second operating phase, new contact combinations are used, the current and voltage paths being varied compared to the first phase. In the third operating phase, an algorithmic scheme that allows cyclic combinations of the contacts is used, the currents and voltage measurements being systematically distributed among different contact groups. This flexible circuit arrangement allows precise detection of the magnetic field components, as the different operating phases can deliver measurement data from multiple perspectives. Cyclic variation of the contact combinations can be used to reduce systematic measurement errors and to minimize interference effects, which can lead to altogether improved accuracy when determining the magnetic field components.

According to some example implementations, the processing unit is configured to determine the magnetic field component Bₓ in proportion to a combination of the voltage between the second and sixth contacts, plus the voltage between the fourth and eighth contacts, plus the voltage between the sixth and eighth contacts, reduced by the voltage between the fourth and second contacts (VB15+VB37+VBE57−VBE31). This takes into account the voltages from the first and fifth operating phases. To determine the magnetic field component B_{y}, the processing unit 140 may be configured to compute B_{y} in proportion to a combination of the voltage between the second and sixth contacts, reduced by the voltage between the fourth and eighth contacts, plus the voltage between the sixth and fourth contacts, and reduced by the voltage between the eighth and second contacts (VB15−VB37+VBE53−VBE71). This takes into account the voltages from the first and fifth operating phases. To compute the magnetic field component B_{z}, the processing unit 140 can combine the measured voltages so that B_{z} is identified in proportion to a combination of the voltage between the first and seventh contacts, reduced by the voltage between the second and fourth contacts, further reduced by the voltage between the third and fifth contacts, and plus the voltage between the eighth and sixth contacts (VB06−VB13−VB24+VB75).

According to another aspect of the present disclosure, a method for detecting magnetic fields using a non-planar Hall effect structure having at least four contacts arranged along edges of the non-planar Hall effect structure is proposed. Multiple operating phases are performed, in each of which (a) current is channeled in through at least two different pairs of contacts and (b) voltages between at least two different pairs of contacts are measured. The voltages measured in the different operating phases are combined and one or more magnetic field components are identified from the combined voltages.

The method for detecting magnetic fields can be implemented by a computer program that controls and evaluates the various steps of the method. The program can be executed on a control unit or a microcontroller connected to the non-planar Hall effect structure and the associated circuit arrangement. In the first step, the computer program ensures that in defined operating phases electric currents are channeled in via specific contact pairs of the Hall effect structure. At the same time, the voltage differences between other, likewise defined contact pairs are measured in each operating phase. The program ascertains these voltage values and stores them in a memory area for subsequent further processing. It combines the voltages measured in the different operating phases using mathematical algorithms stored in the program. Combination is carried out by way of targeted additions, subtractions and/or weightings of the voltage values according to the requirements for identifying the magnetic field components. In the last step, the program computes the magnetic field components by processing the combined voltages using predefined formulae. These computed values can then be stored, displayed or transferred to another processing unit. The computer program therefore allows complete automation of the method, from control of the operating phases, through data acquisition, to evaluation and output of the magnetic field information.

A person skilled in the art will discern further features and advantages of the implementation upon reading the following detailed description and examining the attached drawings.

### BRIEF DESCRIPTION OF THE DRAWINGS

The present disclosure is shown in an example and non-limiting manner in the illustrations of the attached drawings, in which identical reference numbers refer to similar or identical elements. The elements in the drawings are not necessarily depicted to scale in relation to each other. The features of the various examples shown can be combined, provided that they are not mutually exclusive.

FIG. 1A schematically shows a device with a non-planar Hall effect region and multiple contacts;

FIG. 1B shows, by way of illustration, various possible implementations of the non-planar Hall effect region as polyhedral or curved structures;

FIG. 2A shows a pyramidal Hall effect region with four contacts C0-C3 and describes a first operating phase for current and voltage measurement;

FIG. 2B shows a third operating phase in which the flows of current are rotated through 90° compared to FIG. 2A;

FIG. 2C shows a fifth operating phase in which the circuit arrangement uses other contact pairs for supplying and channeling away current;

FIG. 2D illustrates how a processing unit determines the magnetic field components from combinations of the voltages measured in different operating phases;

FIG. 3A shows another implementation with eight contacts C0-C7 arranged symmetrically on a non-planar Hall effect region;

FIG. 3B shows a third operating phase with different current paths and voltage measurements between further contact pairs;

FIG. 3C shows a fifth illustrative operating phase in which two currents are channeled via contacts C5→C3 and C7→C1;

FIG. 3D shows a sixth illustrative operating phase in which two currents are channeled via contacts C3→C1 and C5→C7;

FIG. 3E illustrates how the circuit arrangement and the processing unit combine the measured voltages to identify Bx, By and Bz;

FIG. 3F shows three alternative current patterns in which the contacts are used in a cyclically shifted pattern (mod 8); and

FIG. 4 shows a schematic representation of the device in which the non-planar Hall effect region and the circuit arrangement are combined with multiple transistors to control the current paths.

### DETAILED DESCRIPTION

Just a few possible example implementations of the present disclosure are described below for illustrative purposes. However, it will be readily apparent to a skilled person that the present disclosure is not limited to these specific examples, but can be modified in a variety of ways and adapted for different use cases without departing from the inventive principle.

The detection of magnetic fields in three dimensions is a major challenge in modern sensors. A conventional 3D or 3-axis Hall sensor can detect all three components of an external magnetic field, that is to say Bₓ, B_{y} and B_{z}. This is typically done by combining a classic Hall plate for the vertical magnetic field component B_{z} and two additional vertical Hall elements for detecting the horizontal components Bₓ and B_{y}. However, there are significant challenges, in particular with regard to the consistency of the measured values of the different sensor elements. Over temperature and service life cycles, there may be variances between the classic Hall plate and the vertical Hall sensors, which in practice can lead to measurement errors in the order of around five percent. These variances are a major constraint for precise magnetic field measurements, especially in applications that require high long-term stability and temperature independence.

An improvement over these conventional solutions is to use so-called pyramid Hall effect structures. As described in known approaches, improved consistency between the sensor measured values can be achieved by virtue of the Hall structure being produced not in a planar plane, but in a three-dimensional geometry. For example, an inverted pyramid shape can be etched into a silicon substrate, inclined surfaces of the pyramid being in the form of crystallographic {111} planes. Specific etching solutions can be used that dissolve silicon at different speeds depending on the crystal orientation. In this case, the {100} planes of the silicon are etched faster than the {111} planes, maintaining the {111} planes as inclined lateral faces of the pyramid. Shallow n-wells with a depth of between a few tenths of a micrometre and several micrometres are then implanted in these inclined surfaces of a p-substrate. These wells behave in a functionally similar manner to tilted Hall plates and allow more efficient detection of the magnetic field components. Contacts can be mounted on this pyramid structure, allowing different measurement configurations to be produced. There may also be an additional contact at the tip of the inverted pyramid, which opens up another measurement option. Alternatively, the tip can be removed, creating a truncated pyramid with a square base, at the corners of which additional contacts can be placed.

Targeted current injection via different contacts and the measurement of voltage differences at other contacts can be used to produce different electrical configurations. These configurations are directly dependent on the magnetic field components, so that suitable combination of the measured values allows the individual magnetic field axes to be clearly assigned. It may be advantageous to arrange the contacts not only at the corners of the pyramid base but also at the edges or even completely on the main surface of the substrate. This can not only simplify manufacture of the structures but also lead to improved measurement accuracy.

While the prior art describes various options for detecting the three-dimensional magnetic field components using Hall structures, a major problem remains unsolved. In particular, the known approaches do not yet show a satisfactory method for completely compensating for offset errors within a single pyramidal Hall sensor. In classic Hall plates with four contacts, the offset can usually be reduced by way of the so-called spinning-current method. This involves different contact pairs being used for supplying current and measuring voltage in multiple successive operating phases, as a result of which the systematic offset error can be eliminated. However, this method has not yet been directly transferred to non-planar, three-dimensional Hall structures, and so effective compensation for the offset error continues to be a challenge.

An offset error occurs in a Hall sensor due to unavoidable manufacturing tolerances and material inhomogeneities. Ideally, the output signal from a Hall sensor for an external magnetic field of zero should also be zero. In reality, however, there is a small, non-vanishing offset that can corrupt the measurement result. For classic Hall plates, this raw offset is typically around 1 mT, while for vertical Hall sensors it can even be several mT. By using the spinning-current method, this offset can be reduced, the remaining residual offset being in the region of 10 μT for silicon Hall plates, while for vertical Hall sensors it continues to be in the order of around 100 μT.

The present implementation begins at this juncture and describes an improved concept for completely extracting all three magnetic field components Bₓ, B_{y} and B_{z} from a single non-planar, three-dimensional Hall structure, with the offset error being able to be systematically reduced.

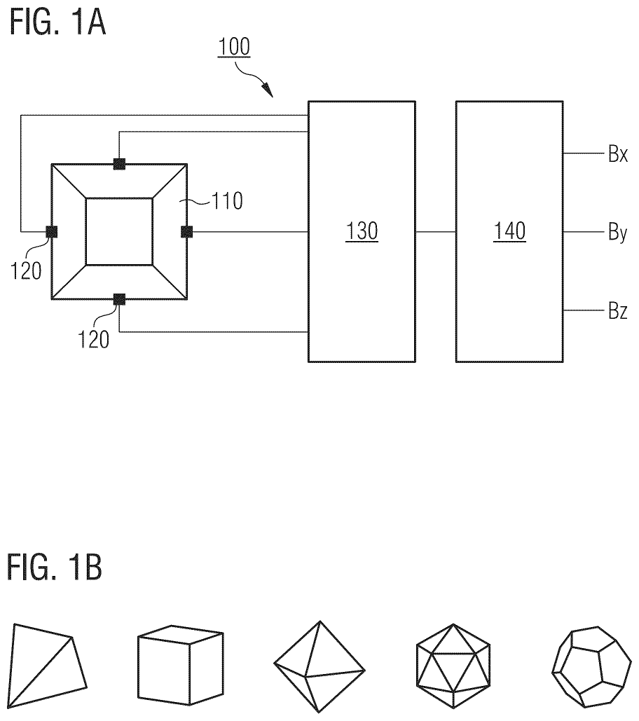

FIG. 1A schematically shows a device 100 for detecting magnetic fields according to one example implementation.

The device 100 generally comprises a non-planar Hall effect region 110, which in its most basic form is a three-dimensional structure for detecting magnetic fields. In contrast to conventional planar Hall elements, this Hall effect region 110 is not limited to a flat surface, but extends in multiple directions in space. Due to its non-planar geometry, it allows differentiated interaction with magnetic fields and can thus be used for versatile applications in sensors.

Non-planar, three-dimensional Hall structures of this kind can be produced, for example, by a combination of lithographic processes, epitaxial growth and controlled etching processes in semiconductor material. First, a suitable mask can be applied by way of precise photolithography to define areas in which material is to be removed or selectively modified. Anisotropic and/or isotropic etching steps can then be carried out in which inclined or curved surfaces are revealed, which can be achieved, in particular with silicon, by way of wet chemical etching agents such as potassium hydroxide. Epitaxial growth can be used to build up additional layers that can also be doped in a deliberate manner in order to adapt electrical properties for desired active areas. A combination of these processes ultimately results in non-planar structures that, thanks to their inclined or curved surfaces, afford improved access to the magnetic field components acting in different spatial directions.

For example, the non-planar Hall effect region 110 may have the shape of an inverted or truncated pyramid whose inclined surfaces form crystallographically defined {111} planes. Alternatively, the non-planar Hall effect region 110 may be in the form of a section of a spherical surface, as a result of which the curved structure allows current distribution in a spherical geometry. Another option is a conical Hall effect region that involves the oblique lateral faces being used as active areas for detecting the magnetic field components. In addition, the non-planar Hall effect region 110 may be in the form of a general polyhedron having multiple inclined surfaces, as a result of which different crystal orientations can be used to achieve improved sensitivity in different spatial directions. Some examples of possible polyhedral structures are shown in FIG. 1B.

The device 100 further comprises a plurality of contacts 120, including at least four contacts, arranged along a border of the non-planar Hall effect region 110. The contacts 120 allow the Hall effect region 110 to be electrically connected to external circuit elements and are used to control and measure electrical signals within the device 100 or Hall effect region 110. The arrangement of the contacts 120 along a border of the Hall effect region 110 ensures targeted interaction with the electrical structure of the device and allows the Hall effect region 110 to be used for detecting magnetic fields.

The contacts 120 can be placed so that they can channel electric currents in defined paths through the non-planar Hall effect region 110. Depending on the operating phase, a current can be injected between specific contact pairs while voltage differences between other contact pairs are measured. This arrangement allows for targeted control of the flows of current so that different magnetic field components can be extracted from the measured voltage values. The placement of the contacts 120 along the border (or edges) ensures that the electric currents can propagate within the non-planar structure, optimizing the collection of magnetic field information.

In one concrete design, as indicated in FIG. 1A, the at least four contacts may be positioned along the edges of a base of an inverted or truncated pyramid structure, as a result of which different contact pairs can be used for supplying current and measuring voltage in each of multiple operating phases. Alternatively, the contacts may be arranged at the vertices or along the centers of the edges of the base of a polyhedral or curved Hall effect structure. Their exact placement may be configured to allow a balanced current distribution and to minimize the effect of offset errors. A deliberate combination of voltages identified from different operating phases can be used to determine the three orthogonal magnetic field components Bₓ, B_{y} and B_{z} and to reduce interference signals, ensuring higher accuracy of the measurements.

The device 100 further comprises a circuit arrangement 130 configured so as, in each of different operating phases, to channel current through at least two different pairs of contacts 120 and to measure voltages between at least two other pairs of contacts. The circuit arrangement 130 allows currents to be carried through the device in a deliberate manner and ensures that voltages can be ascertained at defined points. The organization of operation in different phases can ensure structured and controlled interaction between the electrical signals and the device.

The circuit arrangement 130 may be configured so that it can control the flow of current through at least two different pairs of contacts 120 in different operating phases. At the same time, it measures voltage differences between at least two other contact pairs. This targeted control allows systematic ascertainment of the electrical properties of the device 100 and ensures that different measurement configurations can be produced. The cyclic change of operating phases uses different combinations of current paths and voltage measurements to obtain comprehensive information about the electrical and magnetic interaction within the device.

In one specific implementation, the circuit arrangement 130 may be realized as an electronic control circuit that performs programmable switching operations to select different contact pairs for supplying current and measuring voltage in each operating phase. For example, it can interact with the non-planar Hall effect structure 110 so that in a first phase a current is injected between two specific contacts and at the same time voltage differences between other defined contacts are detected. In the next phase, the current and voltage paths are varied to allow for comprehensive characterization of the magnetic field components. This cyclic switching allows the circuit arrangement 130 to minimize offset errors and achieve improved measurement accuracy by combining and analysing different measured values.

The device 100 further comprises a processing unit 140 configured to identify various magnetic field components Bₓ, B_{y} and B_{z}by way of different combinations of the measured voltages from the different operating phases. The processing unit 140 processes the measured values from the different operating phases and extracts relevant information therefrom. It transforms raw data into a usable form, thereby allowing meaningful interpretation of the physical processes.

The processing unit 140 may be configured to systematically combine the voltages measured in the different operating phases. Targeted mathematical operations can be used to calculate the voltage values so that the individual magnetic field components Bₓ, B_{y} and B_{z} can be isolated. This can be done by applying specific algorithms that use various weights and combinations of the voltages to allow clear separation of the magnetic field directions. The processing unit thus ensures that clear information about the spatial distribution of the magnetic field is extracted from a large volume of measurement data.

In one concrete implementation, the processing unit 140 may be realized as a digital computing unit, for example a microcontroller or a specialized signal processor. It may be configured to apply mathematical operations such as additions, subtractions, or weighted linear combinations to the voltage measured values to determine the individual magnetic field components Bₓ, B_{y} and B_{z}. This targeted signal processing allows the device 100 to deliver precise and reliable measured values by reducing interference signals and compensating for systematic errors such as offset drift.

A basic idea, therefore, is to select a group of contacts on the non-planar Hall effect region 110 and to define a series of operating phases. In each operating phase, specific output voltages are measured and it is stipulated how these are combined. It is then shown that the resulting signal only responds to a single magnetic field component with sufficient sensitivity. At the same time, it is demonstrated that the signal offset averages out as a result of the chosen arrangement of the operating phases and voltage measurements.

There now follows a description of an example implementation in which precisely four contacts are arranged in the respective centers of the edges of a base of a pyramidal Hall effect region 110. The pyramid either has a tip or is flattened on its upper side with or without a hole, this being irrelevant to the principle of operation, however. The circuit arrangement 130 in this instance is configured so that in each of at least three operating phases different pairs of the contacts are used for channeling in currents and there is provision for different voltage taps. This example serves to illustrate a specific configuration of the device 100 and how it works.

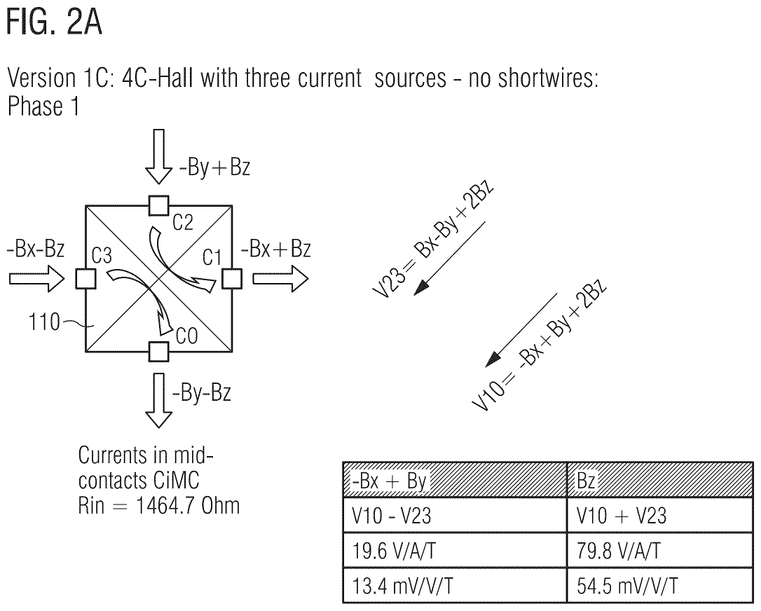

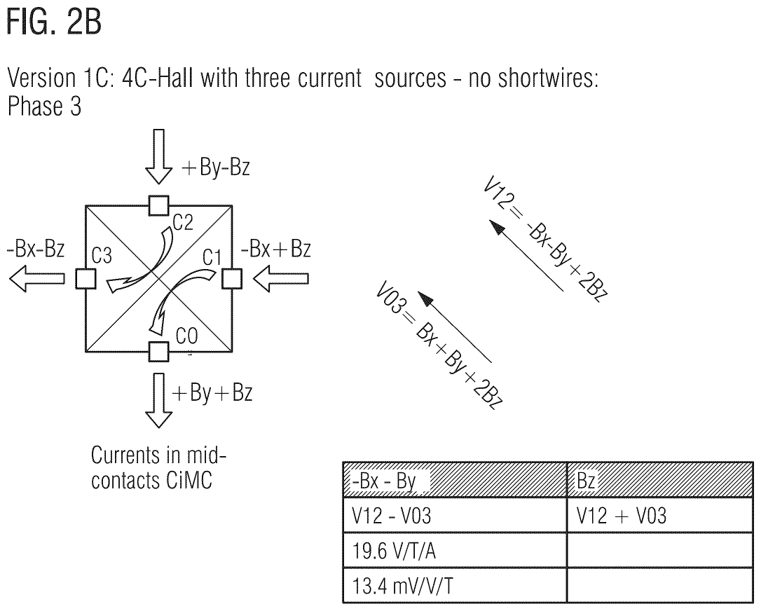

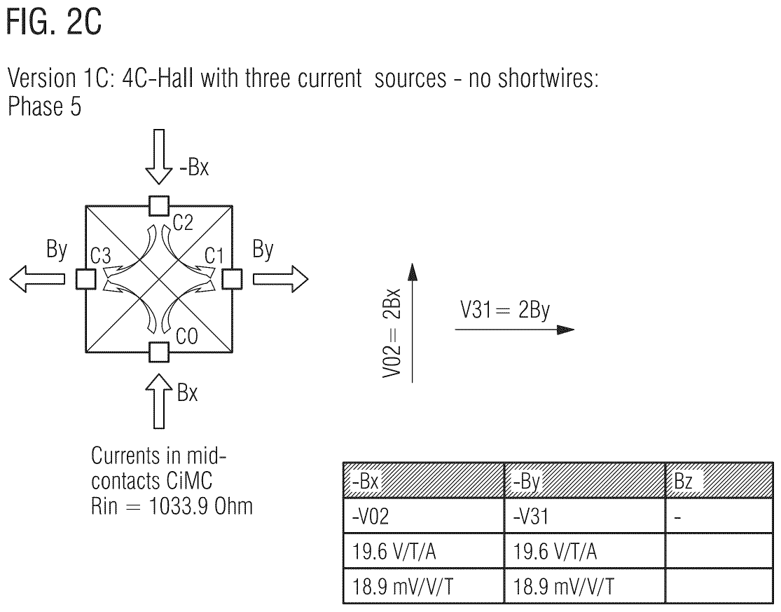

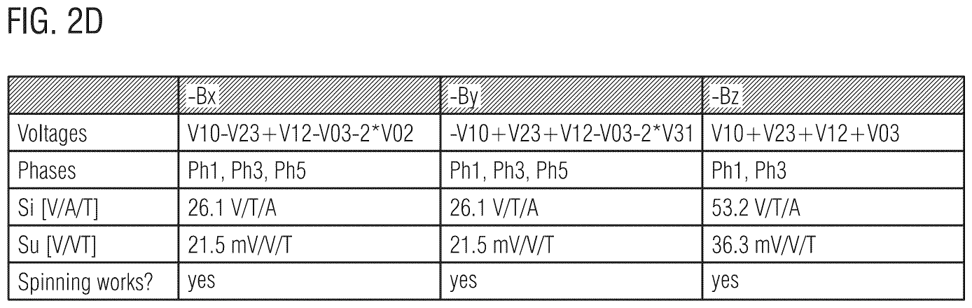

FIG. 2A schematically shows a pyramidal Hall effect region 110 that has precisely four contacts C0-C3 arranged in the respective centers of the edges of a square base of the pyramidal Hall effect region 110. It is important to note that, in addition to a square base, rectangular bases are also conceivable, the contacts being able to be positioned accordingly in the centers of the edges of the rectangle.

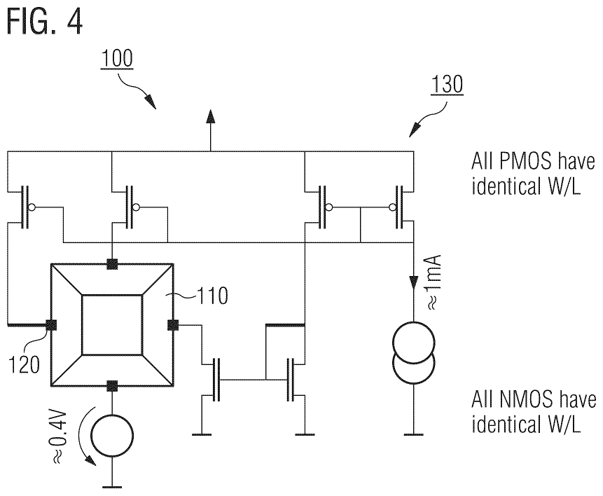

FIG. 2A shows a first operating phase of a spinning scheme in which the circuit arrangement 130 channels a first current into the contact C2 and channels it out of the contact C1. This can be accomplished by connecting the contact C2 to a current source, for example, and the contact C1 to earth. The first current then flows from contact C2 over two adjacent inclined surfaces of the pyramidal Hall effect region 110 to the contact C1. In the first operating phase, the circuit arrangement 130 further channels a second current into the contact C3 and out of the contact C0. This can be accomplished by connecting the contact C3 to a current source and the contact C0 to earth. The second current then flows from contact C3 over two other adjacent inclined surfaces of the pyramidal Hall effect region 110 to the contact C0. However, it should be noted that the two contacts, C1 and C0, are not connected to earth at the same time. Instead, in a practical implementation, such as in the circuit shown in FIG. 4, one of the two contacts is defined as a reference-earth potential (e.g., earth), while the other is controlled using a controlled current source or a corresponding circuit branch to ensure a defined current split. The two currents are preferably of equal magnitude, but directed in opposite directions, in order to ensure a balanced current distribution within the Hall effect region 110 and to minimize measurement errors due to unbalanced current paths. The respective current paths run over two inclined surfaces of the Hall effect region and are separate from one another when the magnetic field is zero, meaning that the two currents are carried independently of one another. However, if an external magnetic field is present, it can affect the current distribution within the Hall effect region, which can result in a complex, unbalanced current distribution.

By way of example, the x-axis here runs horizontally and points from left to right, the y-axis is in the plane of the drawing and points from the bottom edge of the page to the top edge of the page, while the z-axis points out of the plane of the drawing perpendicular thereto. In the first operating phase, the circuit arrangement 130 measures a first voltage V23 between the contact C2 and the contact C3 and a second voltage V10 between the contact C1 and the contact C0. Taking into account the specified coordinate axes, the voltage V23 is proportional to Bₓ−B_{y}+2B_{z}. The voltage V10 is proportional to −Bₓ+B_{y}+2B_{z}. This means that a sum of the voltages V10+V23 can be used to infer B_{z} and a difference between the voltages V10−V23 can be used to infer −Bₓ+B_{y}.

In an optional second operating phase, the circuit arrangement 130 can channel the currents with an opposite current flow, meaning that the arithmetic signs of the supplied currents are reversed. This would involve the first current flowing from contact C1 to contact C2, while the second current is channeled from contact C0 to contact C3. In this operating phase too, corresponding voltages can be measured again, resulting in further data acquisition to determine the magnetic field components.

FIG. 2B shows a third operating phase in which the circuit arrangement 130 channels a first current into the contact C1 and channels it out of the contact C0. This can be accomplished by connecting the contact C1 to a current source and the contact C0 to earth. The first current then flows from contact C1 over two adjacent inclined surfaces of the pyramidal Hall effect region 110 to the contact C0. In the third operating phase, the circuit arrangement 130 further channels a second current into the contact C2 and out of the contact C3. This can be accomplished by connecting the contact C2 to a current source and the contact C3 to earth. Again, it should be noted that the two contacts, C0 and C3, are not connected to earth at the same time. The second current then flows from contact C2 over two other adjacent inclined surfaces of the pyramidal Hall effect region 110 to the contact C3. The two currents are preferably of equal magnitude, but directed in opposite directions, in order to ensure a balanced current distribution within the Hall effect region 110 and to minimize measurement errors due to unbalanced current paths. The respective current paths run over two inclined surfaces of the Hall effect region and do not cross, meaning that the two currents are carried independently of one another (in the absence of a magnetic field).

Compared to the first operating phase shown in FIG. 2A, the flows of current in the third operating phase according to FIG. 2B are rotated through 90° clockwise. Whereas, in the first operating phase, the first current flows between the contacts C2 and C1 and the second current flows between the contacts C3 and C0, the currents in the third operating phase run between the contact pairs C1 and C0 and C2 and C3, which are each rotated one position further. This rotation of the current directions results in an alternative current distribution within the Hall effect region 110, which creates a further measurement configuration that helps to completely detect the magnetic field components and can minimize offset errors further.

In the third operating phase, the circuit arrangement 130 measures a first voltage V12 between the contact C1 and the contact C2 and a second voltage V03 between the contact C0 and the contact C3. The voltage V12 is proportional to −Bₓ−B_{y}+2B_{z}. The voltage V03 is proportional to Bₓ+B_{y}+2B_{z}. This means that a sum of the voltages V12+V03 can be used to infer B_{z} and a difference between the voltages V11−V03 can be used to infer −Bₓ−B_{y}.

In an optional fourth operating phase, the circuit arrangement 130 can channel the currents with an opposite current flow, meaning that the arithmetic signs of the supplied currents are reversed in comparison with the third operating phase. This would involve the first current flowing from contact C0 to contact C1, while the second current is channeled from contact C3 to contact C2. In this operating phase too, corresponding voltages can be remeasured, and so further data acquisition is carried out to determine the magnetic field components.

FIG. 2C shows a fifth operating phase in which the circuit arrangement 130 channels a first current into the contact C0 and away via the contact C1 or the contact C3. This can be accomplished by connecting the contact C0 to a current source and the contact C1 or the contact C3 to earth. The first current then flows from contact C1 over adjacent inclined surfaces of the pyramidal Hall effect region 110 to the contact C1 or contact C3. In the fifth operating phase, the circuit arrangement 130 further channels a second current into the contact C2 and away via the contact C3 or contact C1. This can be accomplished by connecting the contact C2 to a current source and the contact C3 or the contact C1 to earth. Again, it should be noted that the two contacts, C1 (or C3) and C3 (or C1), are not connected to earth at the same time. The second current then flows from contact C2 over other adjacent inclined surfaces of the pyramidal Hall effect region 110 to the contact C3 or contact C1. The respective current paths run over inclined surfaces of the Hall effect region and do not cross in the absence of a magnetic field, meaning that the two currents are carried independently of one another.

In the fifth operating phase, the circuit arrangement 130 measures a first voltage V02 between the contact C0 and the contact C2 and a second voltage V31 between the contact C3 and the contact C1. The voltage V02 is proportional to 2Bₓ. This can be used to infer Bₓ. The voltage V31 is proportional to 2B_{y}. This can be used to infer B_{y}.

In an optional sixth operating phase, the circuit arrangement 130 can channel the currents with an opposite current flow, meaning that the arithmetic signs of the supplied currents are reversed in comparison with the fifth operating phase. This would involve the first current flowing from the contact C1 or C3 towards the contact C0, while the second current is channeled from the contact C3 or C1 towards the contact C2. In this operating phase too, corresponding voltages can be remeasured, and so further data acquisition is carried out to determine the magnetic field components.

As indicated in FIG. 2D, the processing unit 140 may, according to the example implementation described, be configured so that it identifies the magnetic field components Bₓ, B_{y} and B_{z} by way of a deliberate combination of the voltages measured in the different operating phases. For this purpose, it can mathematically combine the voltages from multiple operating phases in order to isolate the individual magnetic field components from the voltage measured values. In particular, the processing unit may be configured to determine Bₓ in proportion to V10−V23+V12−V03−2*V02, the voltages from different phases being calculated in a specific linear combination to ensure a clear dependency on the Bₓ component. To identify the magnetic field component B_{y}, the processing unit 140 may be configured to use a mathematical combination of the voltages that involves B_{y} being computed in proportion to −V10+V23+V12−V03−2*V31. The specific weighting and arithmetic sign of the voltages ensures that B_{y} can be determined separately from the other magnetic field components. To compute the magnetic field component B_{z}, the processing unit 140 can combine the measured voltages so that B_{z} is identified in proportion to V10+V23+V12+V03. This involves the voltages from the relevant operating phases being summed to allow signal processing in which the contributions of the Bₓ and B_{y} components cancel each other out and only the B_{z} component is left. As a result of this targeted processing of the voltage values, the device 100 can allow precise determination of all three orthogonal magnetic field components.

The spinning scheme described based on FIG. 2A-D works by supplying two currents to two of the contacts and removing them again from the other two contacts. For this purpose, the circuit arrangement 130 requires a total of three current sources, since the fourth contact can be connected to a reference potential, for example earth (GND). The circuit arrangement 130 contains switches that allow a current source to be connected to different contacts during the different operating phases. In addition, voltage measuring devices (e.g., high-impedance preamplifiers) are present that measure the voltages between two contacts. The inputs of these preamplifiers are also connected to different contacts of the pyramid via switches so that they can be connected to different measuring points depending on the operating phase.

In this example, the edge length of the square base is 50 μm. The Hall mobility of the n-doped material is −0.1/T. The thickness of the Hall region in each triangular lateral face is 1 μm. The electrical conductivity of the material is 480 S/m. The supply current I_{supply} is 1 mA, which is the total flow of current through the component. Since two equal currents are supplied, each individual current is 0.5 mA.

The schema comprises the operating phases 1, 3, and 5. Optionally, the phases 2, 4 and 6 can be added, which have a reverse polarity for all currents and measured voltages V10, V23, V12, V03, V02 in comparison with the phases 1, 3 and 5.

The measured voltages V10, V23, V12, V03, V02 all disappear when the magnetic field disappears and the pyramid hall device is perfectly symmetrical and the absolute value of the current through all contacts is identical. Thus, the combinations of the voltages that are indicated in FIG. 2D then also disappear, which is consistent with the fact that the magnetic field disappears (Bx=By=Bz=0). However, the combinations of the voltages that are indicated in FIG. 2D still have the property that they disappear even if the magnetic field is zero and the pyramid hall device is non-symmetrical. This statement is synonymous with the finding that the spinning-current method of FIGS. 2A-D eliminates the zero-point error in all three signals Bx, By, Bz. The proof can be obtained by, given a zero magnetic field, replacing a non-symmetrical pyramid hall device with a resistor network comprising six different resistors between all contact combinations, calculating the potentials according to the embossed currents and combining the potentials according to FIG. 2D: zero is obtained for the Bx, By, and Bz combinations (regardless of the values of the six resistors).

For these voltages, it holds that Vij=Vi−Vj, where Vi (Vj) means the potential at contact i (j) with respect to a reference-earth point (earth). Instead of the combination Vij+2*Vkp, it is thus also possible to measure Vi−Vj+2*Vk−2*Vp, in which case the voltmeter measures between one contact and earth and not between two contacts. In practice, it is easier and more accurate if the voltmeter is located directly between contacts i and j and not between contact i and earth and contact j and earth. In addition, the following signal combinations are identical: Vij−Vkp=Vpk−Vji because both sides are identical to Vi−Vj−Vk+Vp.

In a signal processing system, the voltage values can also be integrated over certain time intervals and then combined. Instead of calculating Vij−Vkp, the signal processing can thus also calculate Vij*T−Vkp*T, where, by way of illustration, it integrates Vij over a time interval of length T to obtain Vij*T. Instead of calculating Vij−2*Vkp, however, the signal processing unit can also integrate Vij during a time period T and integrate Vkp during a double time period 2*T and subtract the two intermediate results afterwards.

It is known that dynamic errors (as a result of charge injection during the switching of electrical switching transistors or parasitic line capacitances, or thermal drift due to self-heating of the Hall device or the circuit) can be largely eliminated by varying the timing of the individual clock phases, so that the circuit does not just finish a rigid sequence of phases (e.g., 1-2-3-4-5-6-1-2-3-4-5-6-1-2-3-4-5-6 . . . ), but alters the sequence (e.g., 1-2-3-4-5-6-2-1-4-2-3-6-5 . . . or 1-2-3-4-5-6-6-5-4-3-2-1-1-2-3-4-5-6-6-5- . . . or 1-2-3-4-5-6-1-2-5-6-3-4- . . . ).

In a real circuit, two or three current sources (or current mirrors) are used to force the currents through the four contacts C0 . . . C3, resulting in small differences in the currents (due to mismatch errors in the current mirrors). The offset elimination of the method of FIG. 2A-D then no longer works perfectly. However, it is known in the prior art that such mismatch problems can be countered by way of DEM (Dynamic Element Matching). For this purpose, current mirror outputs Ii, Ij are connected to contacts Ci, Cj in a first phase in a first sequence of the spinning method, but to contacts Cj, Ci (e.g., the contacts are interchanged) in the first phase in a second sequence of the spinning method. Since the currents Ii, Ij are nominally identical and only differ slightly (by a few tenths of a percent) as a result of small mismatch errors, swapping the two current sources also causes only small differences in the measured voltages. In the first sequence of the spinning method, the mismatch error of the two current sources Ii, Ij means that the measured output voltage Vkp is slightly greater than that for perfectly identical currents Ii=Ij, but in the second sequence of the spinning method, Vkp is then smaller by the same absolute value than with perfectly identical currents Ii=Ij. The signals of the two sequences are averaged in the signal processing device, and so the mismatch errors stand out. This averaging can also be accomplished by low-pass filtering if the time constant of the low-pass filter is significantly longer than the time duration of the sum of the two spinning sequences.

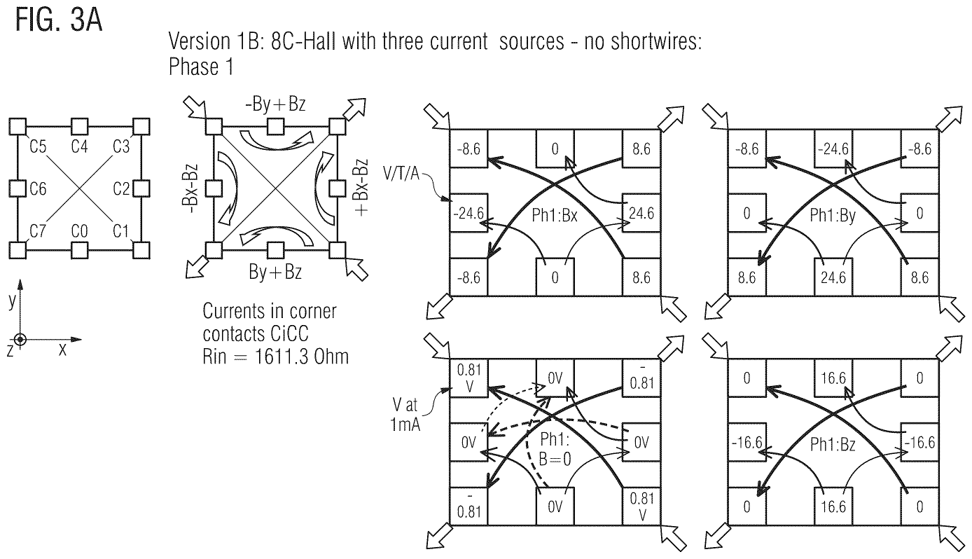

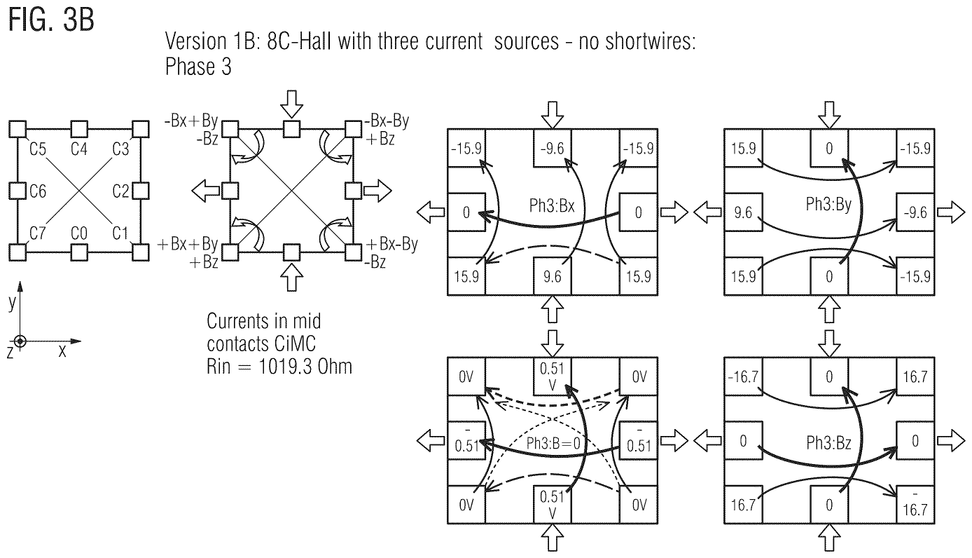

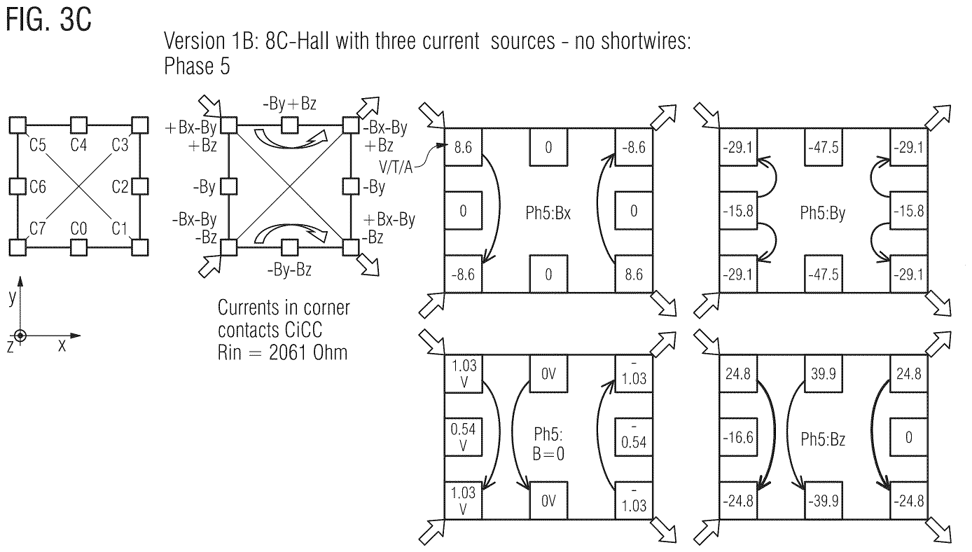

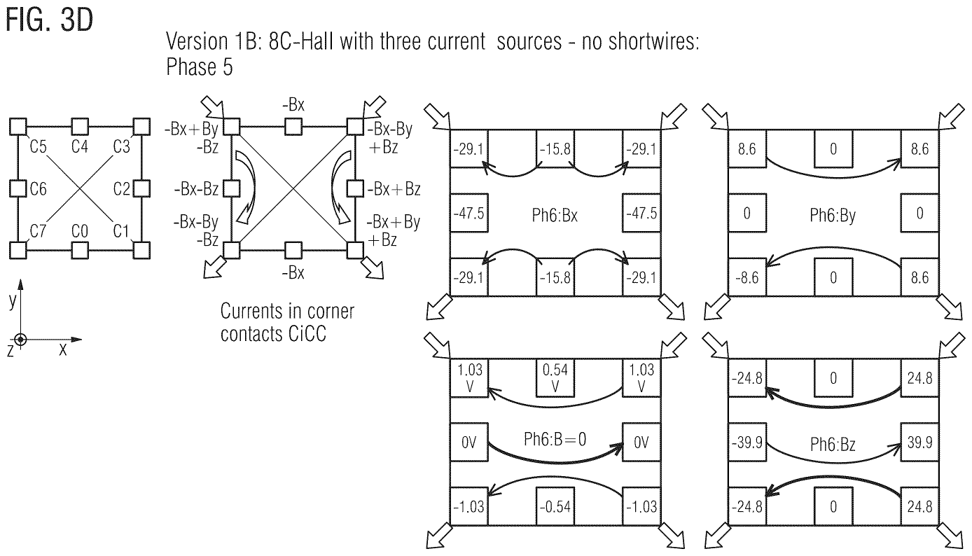

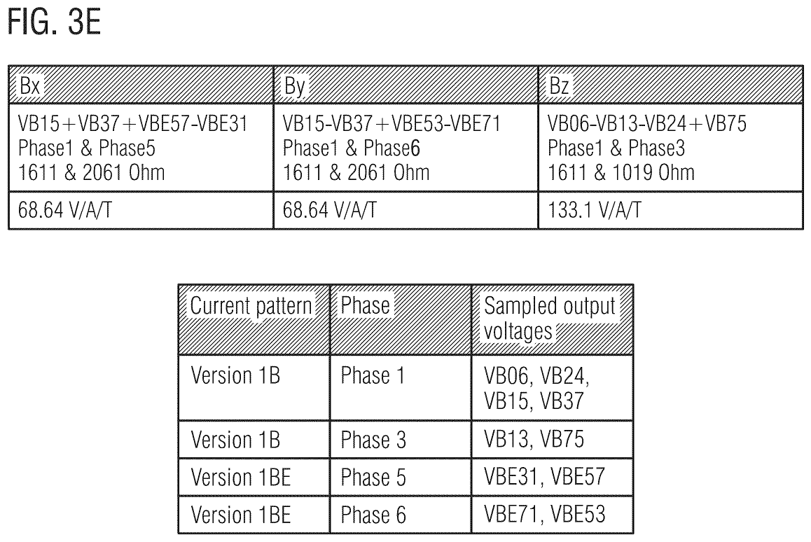

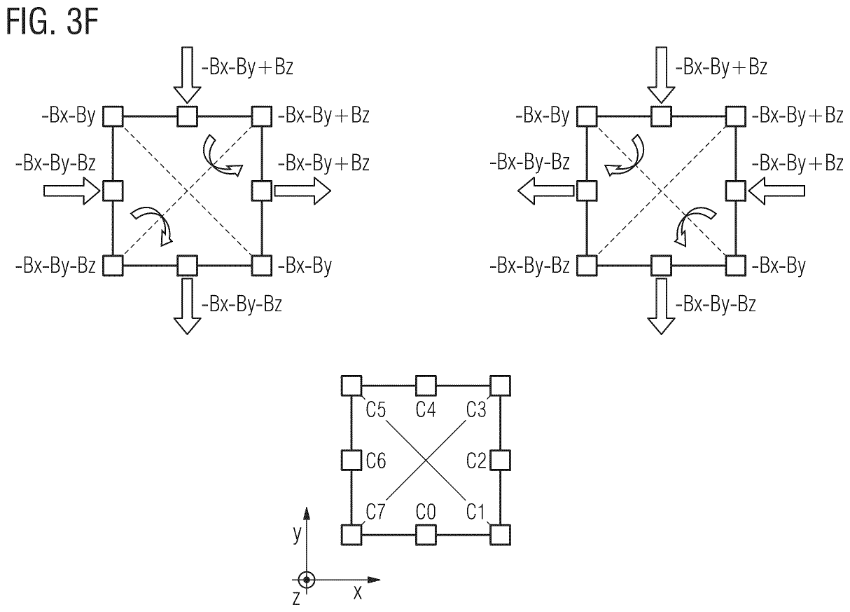

FIG. 3A schematically shows a non-planar Hall effect region 110 according to another example implementation, which has precisely eight contacts C0-C7 arranged both in the corner areas and in the centers of the edges of a base of the non-planar Hall effect region 110. This arrangement allows more flexible selection of the current paths and voltage measuring points in the different operating phases. The symmetrical distribution of the contacts allows more precise detection of the magnetic field components to be carried out by using different contact pairs for supplying current and measuring voltage in each operating phase.

FIG. 3A shows a first illustrative operating phase in which the circuit arrangement 130 channels a first current into the contact C1 and away via the contact C3 or C7. This can be accomplished by connecting the contact C1 to a current source, for example, and the contact C3 or C7 to earth. The first current then flows from contact C1 over at least one inclined surface of the non-planar Hall effect region 110 to the contact C3 or C7. In the first operating phase, the circuit arrangement 130 further channels a second current into the contact C5 and away via the contact C7 or C3. This can be accomplished by connecting the contact C5 to a current source and the contact C7 or C3 to earth. Again, it should be noted that the two contacts, C3 (or C7) and C7 (or C3), are not connected to earth at the same time. The second current then flows from contact C5 over at least one other adjacent inclined surface of the non-planar Hall effect region 110 to the contact C7 or C3. The two currents are preferably of equal magnitude, but directed in opposite directions. The respective current paths run over inclined surfaces of the Hall effect region and do not cross in the absence of a magnetic field, meaning that the two currents are carried independently of one another.

In the first operating phase, the circuit arrangement 130 measures a first voltage VB15 between the contact C1 and the contact C5, a second voltage VB06 between the contact C0 and the contact C6. a third voltage VB24 between the contact C2 and the contact C4, and a fourth voltage VB37 between the contact C3 and the contact C7. Deliberate combination of these voltages can be used to infer various magnetic field components.

In an optional second operating phase, the circuit arrangement 130 can channel the currents with an opposite current flow, meaning that the arithmetic signs of the supplied currents are reversed. This would involve the first current flowing from the contact C3 or C7 towards the contact C1, while the second current is channeled from the contact C7 or C3 towards the contact C5. Since all currents in this operating phase are reversed, all measured voltages will also be reversed compared to the first operating phase, e.g., each voltage will now have the opposite arithmetic sign. This allows balanced data acquisition, allowing systematic errors to be reduced and offsets to be better compensated for. The remeasurement of the voltages in this operating phase thus delivers additional data for more accurate determination of the magnetic field components.

FIG. 3B shows a third illustrative operating phase in which the circuit arrangement 130 channels a first current into the contact C0 and away via the contact C2 or C6. In addition, a second current is supplied to contact C4 and carried away via the contact C6 or C2.

In this operating phase too, the circuit arrangement 130 measures multiple voltage differences between different contact pairs, including VB13 between C1 and C3 and VB75 between C7 and C5. These voltage measurements allow further determination of the magnetic field components.

In an optional fourth operating phase, the circuit arrangement 130 can channel the currents with an opposite current flow, meaning that the arithmetic signs of the supplied currents are reversed. This would involve the first current flowing from the contact C2 or C6 towards the contact C0, while the second current is channeled from the contact C6 or C2 towards the contact C4. Since all currents in this operating phase are reversed, all measured voltages will also be reversed compared to the third operating phase, e.g., each voltage will now have the opposite arithmetic sign. This allows balanced data acquisition, allowing systematic errors to be reduced and offsets to be better compensated for. The remeasurement of the voltages in this operating phase thus delivers additional data for more accurate determination of the magnetic field components.

FIG. 3C shows a fifth illustrative operating phase in which the circuit arrangement 130 channels a first current into the contact C5 and away via the contact C3. A second current is supplied to the contact C7 and channeled away via the contact C1. In this configuration, the circuit arrangement 130 measures various voltages, including VBE57 between C5 and C7 and VBE31 between C3 and C1. These measured values provide additional information for determining the magnetic field components.

In an optional operating phase 5′, the circuit arrangement 130 can channel the currents with an opposite current flow, meaning that the arithmetic signs of the supplied currents are reversed. This would involve the first current flowing from contact C3 to contact C5, while the second current is channeled from contact C1 to contact C7. In this operating phase too, corresponding voltages can be remeasured, and so further data acquisition is carried out to determine the magnetic field components.

FIG. 3D shows a sixth illustrative operating phase in which the circuit arrangement 130 channels a first current into the contact C3 and away via the contact C1. A second current is supplied to the contact C5 and channeled away via the contact C7. In this configuration, the circuit arrangement 130 measures various voltages, including VBE53 between C5 and C3 and VBE71 between C7 and C1. These measured values provide additional information for determining the magnetic field components.

In an optional operating phase 6′, the circuit arrangement 130 can channel the currents with an opposite current flow, meaning that the arithmetic signs of the supplied currents are reversed. This would involve the first current flowing from contact C7 to contact C5, while the second current is channeled from contact C1 to contact C3. In this operating phase too, corresponding voltages can be remeasured, and so further data acquisition is carried out to determine the magnetic field components.

As indicated in FIG. 3E, the processing unit 140 may, according to the example implementation described, be configured so that it identifies the magnetic field components Bₓ, B_{y} and B_{z} by way of a deliberate combination of voltages measured in the different operating phases. For this purpose, it can mathematically combine the voltages from multiple operating phases in order to isolate the individual magnetic field components from the voltage measured values. In particular, the processing unit may be configured to determine the magnetic field component Bₓ in proportion to a combination of the voltages VB15+VB37+VBE57−VBE31. This takes into account the voltages from the first and fifth operating phases. To identify the magnetic field component B_{y}, the processing unit 140 may be configured so that it uses a mathematical combination of the voltages VB15−VB37+VBE53−VBE71. This takes into account the voltages from the first and sixth operating phases. To compute the magnetic field component B_{z}, the processing unit 140 can combine the measured voltages so that B_{z} is identified in proportion to a combination of the voltages VB06−VB13−VB24+VB75. This takes into account the voltages from the first and third operating phases. This involves the voltages from the relevant operating phases being summed and subtracted to allow signal processing in which the contributions of the Bₓ and B_{y} components cancel each other out and only the B_{z} component is left. As a result of this targeted processing of the voltage values, the device 100 can allow precise determination of all three orthogonal magnetic field components.

FIG. 3C shows an illustrative fifth operating phase in which the circuit arrangement 130 channels a first current into the contact C5 and away via the contact C3. A second current is supplied to the contact C7 and channeled away via the contact C1. In this configuration, the circuit arrangement 130 measures various voltages, including VBE57 between C5 and C7 and VBE31 between C3 and C1. These measured values provide additional information for determining the magnetic field components.

Due to the symmetry of the arrangement, instead of the operating phase shown in FIG. 3C, an alternative operating phase could also be used in which the currents are channeled through the contacts in a cyclically shifted pattern. The current pattern can be rotated through a defined number of contact positions, meaning that new contact pairs are used for supplying and channeling away current instead of the original contacts. This results in an equivalent mode of operation in which the measured voltage differences can still be used to identify the magnetic field components. Two other alternative current patterns are shown in FIG. 3F.

The left of FIG. 3F shows an illustrative fifth operating phase in which the circuit arrangement 130 channels a first current into the contact C6 and away through the contact C0. A second current is supplied to the contact C4 and channeled away via the contact C2. The right of FIG. 3F shows another alternative fifth operating phase in which the circuit arrangement 130 channels a first current into the contact C4 and away through the contact C6. A second current is supplied to the contact C2 and channeled away via the contact C0.

In the operating phases shown, it can be seen that the respective current paths occur in pairs that are offset from one another by a specific number of contact positions (modulo 8). For example, the supplying and away-channeling contacts are always two positions apart (e.g., C5→C7 or C5→C3), and the second current-carrying arrangement is shifted accordingly through another two positions (for instance C3→C1 or C7→C1). Due to the eight-contact cyclicality, this pattern can generally be transferred to other contact pairs by way of a rotation (that is to say addition of a fixed offset “mod 8”). This results in equivalent operating phases in which, although other contacts are used, the geometric and functional symmetry of the arrangement is maintained.

FIG. 4 shows a schematic representation of a device 100 comprising a non-planar Hall effect region 110. The Hall effect region 110 here is shown as a pyramidal structure and has multiple electrical contacts 120 arranged along the edges of the base. These contacts allow currents to be supplied and channeled away and voltages to be measured for determining the magnetic field components.

The circuit arrangement 130 comprises multiple transistors that are used to control the current paths and that allow targeted modulation of the current distribution within the Hall effect region 110. The configuration shown can be used to control the operating phases in which currents are channeled through the Hall effect region and voltages are measured at defined points. This arrangement allows the magnetic field components to be detected by way of a deliberate combination of the voltage measured values from different operating phases. In particular, in the circuit arrangement 130, two identical currents are injected into contacts C2, C3 through PMOSFET current mirrors and a current of equal magnitude is drawn from the Hall effect region through the NMOSFET current mirror at contact C1 (assuming that all PMOSFET transistors have identical current gain, in particular that is to say an identical aspect ratio W/L of the MOSFET channel, and all NMOSFET transistors also have identical current gain). Due to Kirchhoff's law, the same current must flow out of contact C0 as out of contact C1. The potential at contact C0, at approximately 0.4V, is set so that the NMOSFET at the contact C1 receives enough drain-source voltage to be able to operate as a current source (its drain-source voltage must thus be greater than the saturation voltage, so that the NMOSFET is operated in the high-impedance horizontal part of the characteristic in the output characteristic field Idrain-versus-Vdrain-source).

In summary, the present disclosure thus describes an improved solution for the three-dimensional detection of magnetic fields using non-planar Hall structures. A targeted arrangement of contacts in combination with a suitable circuit arrangement allows currents to be supplied to the Hall structure via different paths in different operating phases, and voltages to be measured at defined points. In this way, all three magnetic field components Bₓ, B_{y} and B_{z} can be reliably determined from the acquired data, while systematic errors such as offset drift can be significantly reduced by way of suitable switching of the currents and evaluation of the measured values. Thanks to the non-planar geometry—for example in the form of an inverted or truncated pyramid, a cone or a curved section—improved sensitivity is obtained in different spatial directions. The concepts presented can be used for both planar and three-dimensional designs and allow precise detection of all magnetic field components using special measurement and evaluation algorithms that can be flexibly adapted for different contact and current-carrying patterns. This allows both measurement tolerances and manufacturing fluctuations to be reduced, resulting in a long-term stable sensor concept that, thanks to its modular structure, can be used in numerous applications and adapted for different needs without departing from the inventive principle.

It should be pointed out that the description and the drawings only illustrate the principles of the proposed methods and devices. A person skilled in the art will be capable of implementing different arrangements which, although not expressly described or shown here, embody the principles of the implementation and are contained within the scope thereof. In addition, all examples and implementations outlined in the present document are intended fundamentally and expressly for explanatory purposes only, in order to help the reader understand the principles of the proposed methods and devices. In addition, all statements in this document that describe principles, aspects and implementations of the implementation and specific examples thereof are also intended to encompass their equivalents.

### Aspects

The following provides an overview of some Aspects of the present disclosure:
Aspect 1: A device for detecting magnetic fields, comprising: a non-planar Hall effect region; a plurality of contacts, including at least four contacts, arranged along a border of the non-planar Hall effect region; a circuit arrangement configured so as, in each operating phase of different operating phases, to channel in current through at least two different pairs of contacts of the plurality of contacts and to measure voltages between at least two other pairs of contacts of the plurality of contacts; and a processing unit configured to identify various magnetic field components by way of different combinations of the measured voltages from the different operating phases.
Aspect 2: The device according to Aspect 1, wherein the non-planar Hall effect region has a polyhedral structure.
Aspect 3: The device according to Aspect 1, wherein the non-planar Hall effect region has a pyramidal structure with inclined surfaces.
Aspect 4: The device according to Aspect 3, wherein the pyramidal structure is in the form of at least one of an inverted pyramid or a cropped pyramid.
Aspect 5: The device according to Aspect 1, wherein the non-planar Hall effect region is in a doubly connected form and has an annular, non-planar surface.
Aspect 6: The device according to Aspect 1, wherein the plurality of contacts or a portion of the plurality of contacts are arranged in respective centers of edges of a base of the non-planar Hall effect region.
Aspect 7: The device according to Aspect 1, wherein the plurality of contacts or a portion of the plurality of contacts are arranged in respective corner areas of a base of the non-planar Hall effect region.
Aspect 8: The device according to Aspect 1, wherein the circuit arrangement is configured so as, in each operating phase of the different operating phases, to simultaneously channel in at least two currents of equal level via different contacts of the plurality of contacts.
Aspect 9: The device according to Aspect 1, wherein the processing unit is configured to perform various additions and/or subtractions of voltages measured and weighted in the different operating phases for each magnetic field component of the various magnetic field components.
Aspect 10: The device according to Aspect 1, wherein precisely four contacts of the plurality of contacts are arranged in respective centers of edges of a base of the non-planar Hall effect region, and wherein the circuit arrangement is configured so as, in each of at least three operating phases of the different operating phases, to use different pairs of the contacts for channeling in currents and to provide for different voltage taps.
Aspect 11: The device according to Aspect 9, wherein the circuit arrangement is configured so as, in each of at least three operating phases of the different operating phases, to channel two parallel currents between different pairs of the four contacts, and to measure at least two voltage differences between remaining contacts of the four contacts, wherein a different set of contact pairs is used for channeling in current and measuring voltage in each operating phase of the at least three operating phases.
Aspect 12: The device according to Aspect 10, wherein the plurality of contacts include: a first contact being arranged on a first edge of a base of the non-planar Hall effect region, a second contact being arranged on a second edge of the base of the non-planar Hall effect region, a third contact being arranged on a third edge of the base of the non-planar Hall effect region, and a fourth contact being arranged on a fourth edge of the base of the non-planar Hall effect region; and wherein the circuit arrangement is configured so as, in a first operating phase of the different operating phases, to channel in a first current between the third and second contacts, to channel in a second current between the fourth and first contacts, to measure a first voltage between the third and fourth contacts, and to measure a second voltage between the second and first contacts, in a second operating phase of the different operating phases, to inject a first current between the second and first contacts, to inject a second current between the third and fourth contacts, to measure a first voltage between the second and third contacts, and to measure a second voltage between the first and fourth contacts, and in a third operating phase of the different operating phases, to channel a first current into the first contact and away via the second contact, to channel a second current into the third contact and away via the fourth contact, to measure a first voltage between the first and third contacts, and to measure a second voltage between the fourth and second contacts.
Aspect 13: The device according to Aspect 12, wherein the processing unit is configured to: identify a first magnetic field component in proportion to a combination of the voltage between the first and second contacts, reduced by the voltage between the third and fourth contacts, plus the voltage between the second and third contacts, reduced by the voltage between the first and fourth contacts, and minus twice the voltage between the first and third contacts, identify a second magnetic field component in proportion to a combination of a negative voltage between the first and second contacts, plus the voltage between the third and fourth contacts, plus the voltage between the second and third contacts, reduced by the voltage between the first and fourth contacts, and minus twice the voltage between the fourth and second contacts, and identify a third magnetic field component in proportion to a sum of the voltages between the first and second contacts, the third and fourth contacts, the second and third contacts, and the first and fourth contacts.
Aspect 14: The device according to Aspect 1, wherein the plurality of contacts include precisely eight contacts, which are arranged both in corner areas and in middle areas of edges of a base of the non-planar Hall effect region, and wherein the circuit arrangement is configured so as, in each of at least three operating phases of the different operating phases, to use different pairs of the contacts for channeling in currents and to provide for different voltage taps.
Aspect 15: The device according to Aspect 14, wherein the circuit arrangement being configured so as, in each operating phase of the at least three operating phases, to channel at least two simultaneous currents between different subgroups of the eight contacts, and to measure multiple voltage differences between other contact pairs.
Aspect 16: The device according to Aspect 14, wherein the plurality of contacts include: a first contact being arranged at a center of a first edge of a base of the non-planar Hall effect region, a second contact being arranged at a vertex between the first edge and a second edge of the base of the non-planar Hall effect region, a third contact being arranged at a center of the second edge, a fourth contact being arranged at a vertex between the second edge and a third edge of the base of the non-planar Hall effect region, a fifth contact being arranged at a center of the third edge, a sixth contact being arranged at a vertex between the third edge and a fourth edge of the base of the non-planar Hall effect region, a seventh contact being arranged at a center of the fourth edge, and an eighth contact being arranged at a vertex between the fourth edge and the first edge of the base of the non-planar Hall effect region, and wherein the circuit arrangement is configured so as, in a first operating phase of the different operating phases, to channel a first current into the second contact and away via the fourth contact, to channel a second current into the sixth contact and away via the eighth contact, to measure a first voltage between the second and sixth contacts, to measure a second voltage between the first and seventh contacts and to measure a third voltage between the third and fifth contacts and to measure a fourth voltage between the fourth and eighth contacts; wherein the circuit arrangement is configured so as, in a second operating phase of the different operating phases, to channel a first current into the first contact and away via the third contact, to channel a second current into the fifth contact and away via the seventh contact, to measure a first voltage between the second and fourth contacts, and to measure a second voltage between the eighth and sixth contacts; wherein the circuit arrangement is configured so as, in a third operating phase of the different operating phases, to channel a first current into the sixth contact and away via a fourth contact, to channel a second current into an eighth contact and away via the second contact, to measure a first voltage between the sixth and eighth contacts, and to measure a second voltage between the fourth and second contacts; wherein the circuit arrangement is configured so as, in a fourth operating phase of the different operating phases, to channel a first current into a sixth contact and away via an eighth contact, to channel a second current into a fourth contact and away via a second contact, to measure a first voltage between the sixth and fourth contacts, and to measure a second voltage between the eighth and second contacts.
Aspect 17: The device according to Aspect 16, wherein the processing unit is configured to: determine a first magnetic field component in proportion to a combination of the voltage between the second and sixth contacts, plus the voltage between the fourth and eighth contacts, plus the voltage between the sixth and eighth contacts, reduced by the voltage between the fourth and second contacts, determine a second magnetic field component in proportion to a combination of the voltage between the second and sixth contacts, reduced by the voltage between the fourth and eighth contacts, plus the voltage between the sixth and fourth contacts, and reduced by the voltage between the eighth and second contacts, and determine a third magnetic field component in proportion to a combination of the voltage between the first and seventh contacts, reduced by the voltage between the second and fourth contacts, further reduced by the voltage between the third and fifth contacts, and plus the voltage between the eighth and sixth contacts.
Aspect 18: A method for detecting magnetic fields using a non-planar Hall effect structure having at least four contacts arranged along edges of the non-planar Hall effect structure, comprising: performing multiple operating phases, including in each operating phase of the multiple operating phases: channeling in current through at least two different pairs of contacts and measuring voltages between at least two different pairs of contacts; combining the voltages measured in the multiple operating phases; and identifying one or more magnetic field components from the combined voltages.
Aspect 19: A system configured to perform one or more operations recited in one or more of Aspects 1-18.
Aspect 20: An apparatus comprising means for performing one or more operations recited in one or more of Aspects 1-18.

Aspect 21: A non-transitory computer-readable medium storing a set of instructions, the set of instructions comprising one or more instructions that, when executed by a device, cause the device to perform one or more operations recited in one or more of Aspects 1-18.

Aspect 22: A computer program product comprising instructions or code for executing one or more operations recited in one or more of Aspects 1-18.

1. A device for detecting magnetic fields, comprising:
a non-planar Hall effect region;
a plurality of contacts, including at least four contacts, arranged along a border of the non-planar Hall effect region;
a circuit arrangement configured so as, in each operating phase of different operating phases, to channel in current through at least two different pairs of contacts of the plurality of contacts and to measure voltages between at least two other pairs of contacts of the plurality of contacts; and
a processing unit configured to identify various magnetic field components by way of different combinations of the measured voltages from the different operating phases.

2. The device according to claim 1, wherein the non-planar Hall effect region has a polyhedral structure.

3. The device according to claim 1, wherein the non-planar Hall effect region has a pyramidal structure with inclined surfaces.

4. The device according to claim 3, wherein the pyramidal structure is in the form of at least one of an inverted pyramid or a cropped pyramid.

5. The device according to claim 1, wherein the non-planar Hall effect region is in a doubly connected form and has an annular, non-planar surface.

6. The device according to claim 1, wherein the plurality of contacts or a portion of the plurality of contacts are arranged in respective centers of edges of a base of the non-planar Hall effect region.

7. The device according to claim 1, wherein the plurality of contacts or a portion of the plurality of contacts are arranged in respective corner areas of a base of the non-planar Hall effect region.

8. The device according to claim 1, wherein the circuit arrangement is configured so as, in each operating phase of the different operating phases, to simultaneously channel in at least two currents of equal level via different contacts of the plurality of contacts.

9. The device according to claim 1, wherein the processing unit is configured to perform various additions and/or subtractions of voltages measured and weighted in the different operating phases for each magnetic field component of the various magnetic field components.

10. The device according to claim 1, wherein precisely four contacts of the plurality of contacts are arranged in respective centers of edges of a base of the non-planar Hall effect region, and
wherein the circuit arrangement is configured so as, in each of at least three operating phases of the different operating phases, to use different pairs of the contacts for channeling in currents and to provide for different voltage taps.

11. The device according to claim 9, wherein the circuit arrangement is configured so as, in each of at least three operating phases of the different operating phases,
to channel two parallel currents between different pairs of the four contacts, and
to measure at least two voltage differences between remaining contacts of the four contacts,
wherein a different set of contact pairs is used for channeling in current and measuring voltage in each operating phase of the at least three operating phases.

12. The device according to claim 10, wherein the plurality of contacts include:
a first contact being arranged on a first edge of a base of the non-planar Hall effect region,
a second contact being arranged on a second edge of the base of the non-planar Hall effect region,
a third contact being arranged on a third edge of the base of the non-planar Hall effect region, and
a fourth contact being arranged on a fourth edge of the base of the non-planar Hall effect region; and
wherein the circuit arrangement is configured so as,
in a first operating phase of the different operating phases, to channel in a first current between the third and second contacts, to channel in a second current between the fourth and first contacts, to measure a first voltage between the third and fourth contacts, and to measure a second voltage between the second and first contacts,
in a second operating phase of the different operating phases, to inject a first current between the second and first contacts, to inject a second current between the third and fourth contacts, to measure a first voltage between the second and third contacts, and to measure a second voltage between the first and fourth contacts, and
in a third operating phase of the different operating phases, to channel a first current into the first contact and away via the second contact, to channel a second current into the third contact and away via the fourth contact, to measure a first voltage between the first and third contacts, and to measure a second voltage between the fourth and second contacts.

13. The device according to claim 12, wherein the processing unit is configured to:
identify a first magnetic field component in proportion to a combination of the voltage between the first and second contacts, reduced by the voltage between the third and fourth contacts, plus the voltage between the second and third contacts, reduced by the voltage between the first and fourth contacts, and minus twice the voltage between the first and third contacts,
identify a second magnetic field component in proportion to a combination of a negative voltage between the first and second contacts, plus the voltage between the third and fourth contacts, plus the voltage between the second and third contacts, reduced by the voltage between the first and fourth contacts, and minus twice the voltage between the fourth and second contacts, and
identify a third magnetic field component in proportion to a sum of the voltages between the first and second contacts, the third and fourth contacts, the second and third contacts, and the first and fourth contacts.

14. The device according to claim 1, wherein the plurality of contacts include precisely eight contacts, which are arranged both in corner areas and in middle areas of edges of a base of the non-planar Hall effect region, and
wherein the circuit arrangement is configured so as, in each of at least three operating phases of the different operating phases, to use different pairs of the contacts for channeling in currents and to provide for different voltage taps.

15. The device according to claim 14, wherein the circuit arrangement being configured so as, in each operating phase of the at least three operating phases,
to channel at least two simultaneous currents between different subgroups of the eight contacts, and
to measure multiple voltage differences between other contact pairs.

16. The device according to claim 14,
wherein the plurality of contacts include:
a first contact being arranged at a center of a first edge of a base of the non-planar Hall effect region,
a second contact being arranged at a vertex between the first edge and a second edge of the base of the non-planar Hall effect region,
a third contact being arranged at a center of the second edge,
a fourth contact being arranged at a vertex between the second edge and a third edge of the base of the non-planar Hall effect region,
a fifth contact being arranged at a center of the third edge,
a sixth contact being arranged at a vertex between the third edge and a fourth edge of the base of the non-planar Hall effect region,
a seventh contact being arranged at a center of the fourth edge, and
an eighth contact being arranged at a vertex between the fourth edge and the first edge of the base of the non-planar Hall effect region, and
wherein the circuit arrangement is configured so as, in a first operating phase of the different operating phases, to channel a first current into the second contact and away via the fourth contact, to channel a second current into the sixth contact and away via the eighth contact, to measure a first voltage between the second and sixth contacts, to measure a second voltage between the first and seventh contacts and to measure a third voltage between the third and fifth contacts and to measure a fourth voltage between the fourth and eighth contacts;
wherein the circuit arrangement is configured so as, in a second operating phase of the different operating phases, to channel a first current into the first contact and away via the third contact, to channel a second current into the fifth contact and away via the seventh contact, to measure a first voltage between the second and fourth contacts, and to measure a second voltage between the eighth and sixth contacts;
wherein the circuit arrangement is configured so as, in a third operating phase of the different operating phases, to channel a first current into the sixth contact and away via a fourth contact, to channel a second current into an eighth contact and away via the second contact, to measure a first voltage between the sixth and eighth contacts, and to measure a second voltage between the fourth and second contacts;
wherein the circuit arrangement is configured so as, in a fourth operating phase of the different operating phases, to channel a first current into a sixth contact and away via an eighth contact, to channel a second current into a fourth contact and away via a second contact, to measure a first voltage between the sixth and fourth contacts, and to measure a second voltage between the eighth and second contacts.

17. The device according to claim 16, wherein the processing unit is configured to:
determine a first magnetic field component in proportion to a combination of the voltage between the second and sixth contacts, plus the voltage between the fourth and eighth contacts, plus the voltage between the sixth and eighth contacts, reduced by the voltage between the fourth and second contacts,
determine a second magnetic field component in proportion to a combination of the voltage between the second and sixth contacts, reduced by the voltage between the fourth and eighth contacts, plus the voltage between the sixth and fourth contacts, and reduced by the voltage between the eighth and second contacts, and
determine a third magnetic field component in proportion to a combination of the voltage between the first and seventh contacts, reduced by the voltage between the second and fourth contacts, further reduced by the voltage between the third and fifth contacts, and plus the voltage between the eighth and sixth contacts.

18. A method for detecting magnetic fields using a non-planar Hall effect structure having at least four contacts arranged along edges of the non-planar Hall effect structure, comprising:
performing multiple operating phases, including in each operating phase of the multiple operating phases:
channeling in current through at least two different pairs of contacts and
measuring voltages between at least two different pairs of contacts;
combining the voltages measured in the multiple operating phases; and
identifying one or more magnetic field components from the combined voltages.
